(19) United States
(12) Patent Application Publication
(10) Pub. No.: US 2006/0128040 A1
(43) Pub. Date: Jun. 15, 2006

(54) BOND POSITIONING METHOD FOR WIRE-BONDING PROCESS AND SUBSTRATE FOR THE BOND POSITIONING METHOD

(75) Inventors: Chih-Feng Chen, Taichung (TW); Chin Fa Wang, Taichung (TW); Chien-Chih Chen, Taichung (TW)

Correspondence Address: THE LAW OFFICES OF MIKIO ISHIMARU, 333 W. EL CAMINO REAL, SUITE 330, SUNNYVALE, CA, 94087, US

(73) Assignee: SILICONWARE PRECISION INDUSTRIES CO., LTD., Taichung (TW)

(21) Appl. No.: 11/164,319

(22) Filed: Nov. 17, 2005

(30) Foreign Application Priority Data
Dec. 14, 2004 (TW) 93138689

(51) Int. Cl. H01L 21/66; G01R 31/26

(52) U.S. Cl. 438/15

(57) ABSTRACT

A bond positioning method for a wire-bonding process and a substrate for the bond positioning method are provided. At least one solder mask mark is formed in a solder mask layer on the substrate, such that during the wire-bonding process, the solder mask mark serves as a reference point for determining deviation of the solder mask layer and performing coordinate compensation according to the deviation so as to re-define positioning of a second bonding point of a bonding wire. This can overcome defects relating to bonding wires such as bending, cracking, or detachment of the bonding wires caused by undesirable contact between the bonding wires and the solder mask layer in the conventional wire-bonding process, thereby improving the production yield of the wire-bonding process, reducing material costs associated with defective products, and reducing the overall fabrication costs.

### FIELD OF THE INVENTION

The present invention relates to a semiconductor packaging technology, and more particularly, to a bond positioning method for a wire-bonding process and a substrate for the bond positioning method.

### BACKGROUND OF THE INVENTION

Along with advent of the so-called micro-profit era, the issue of how to improve the yield for each process of semiconductor production so as to avoid expenditure for defective products has been always one of the important factors influencing the profit of semiconductor industry. It is the same for those engaged in producing semiconductor packages.

Generally, the fabrication method for the above-mentioned semiconductor packages include the steps of performing a die-bonding process and a wire-bonding process on a surface of a chip carrier such as a substrate, so as to establish an electrical connection between a chip and the substrate, and then performing an encapsulation process and optionally a cutting process, thereby forming a semiconductor package. In the mass-automation manufacturing process employed, the semiconductor packages are usually produced in a batch type method, wherein a plurality of the above-described substrates are integrally arranged in matrix on a substrate strip, and the substrate strip is then transmitted by a carrier to various automation packaging apparatus in sequence, such as die bonding apparatus, wire bonding apparatus and the like, so as to be subjected to a die-bonding operation, wire-bonding operation, encapsulation operation and cutting operation, to thereby form a plurality of semiconductor packages.

To subsequently solder and electrically connect the semiconductor package to an external device with solder balls, or to effectively connect the chip thereof to the substrate, it is necessary to form a plurality of conductive traces, which are, for example, made of copper, on a surface of the substrate, allowing electrical connection portions for signal transmission, such as fingers, solder ball pads and the like, to be exposed from a solder mask layer on the surface of the substrate. A metal layer such as Ni/Au layer is electroplated on a surface of each of the electrical connection portions, so as to allow the chip or the substrate to be effectively electrically coupled to other conductive elements, such as gold wires, solder bumps, or solder balls, as well as to avoid oxidization of the electrical connection portions caused by the outside environment.

A relevant die bonding process and wire-bonding process will now be further described in detail with a conventional BGA (Ball Grid Array) semiconductor package as an example. As shown in FIG. 1 (PRIOR ART) and FIG. 2A (PRIOR ART), a die pad 11 is defined at a central portion on an upper surface of a substrate 1, and a plurality of electrical connection portions 15, 151 and 153 are provided around the die pad 11, wherein the electrical connection portions are formed from parts of conductive traces and exposed from a surface of a solder mask layer 13. Utilizing a die bonding apparatus, the die pad 11 is dispensed with a paste material, and a chip 17 is then attached thereon and thermally cured, thus completing the die bonding process. A plurality of bonding wires 173 are bonded between corresponding bond pads 171 and the electrical connection portions 15, 151, and 153 by a wire bonding apparatus, thereby completing the wire-bonding process. In order to allow the die bonding apparatus to perform the die bonding process with high positioning accuracy, at least one so-called fiducial mark, which is also formed from a part of the conductive traces and is plated with a Ni/Au metal layer on a surface thereof, is provided in advance of die bonding on the upper surface of the substrate 1. The fiducial mark 19 is exposed at a corresponding opening 131 formed in the solder mask layer 13, so that the fiducial mark 19 can be recognized by an image capturing unit of the die bonding apparatus so as to determine coordinate data. Because the color of the solder mask layer 13 is similar to that of the substrate 1, judgment of the fiducial mark 19 with golden color is not influenced by the part of the substrate 1 exposed at the opening 131.

Since the fiducial mark 19 is also formed from a part of the conductive traces of the substrate 1, relative positions between the fiducial mark and the die pad 11 as well as the electrical connection portions 15, 151 and 153 are definitely not changed. Therefore, once the fiducial mark 19 is recognized by the image capturing unit of the die bonding apparatus and the coordinate data is determined, coordinates for the die bonding process are determined, and coordinates for the subsequent wire-bonding process are also determined with respect to data for the chip 17, whereby a first bonding point and a second bonding point of each of the bonding wires 173 can be accurately bonded onto the bond pad 171 of the chip 17 and the electrical connection portion 15 respectively.

However, there is generally a deviation of ±75 μm for the position of each of the openings (including the openings 133 corresponding to the locations of the electrical connection portions, and the opening 131 corresponding to the location of the fiducial mark) in the solder mask layer 13 on the surface of the substrate 1. Since the size of the fiducial mark 19 is usually much bigger than such a tolerance of position deviation, the position of the central portion of the fiducial mark 19 can be easily recognized even when the opening 131 deviates considerably. However, for the electrical connection portions 15, 151 and 153, the position deviation of the corresponding openings thereof would result in various bonding failures such as detachment, bending, or cracking of the bonding wires. The electrical connection portions 15, 151 and 153 are generally classified into ground ring, power ring and finger according to the functionality thereof. Since there is no difference between the wire-bonding processes for those different portions, only the wire-bonding process for the electrical connection portion 15 representing the ground ring will be described in the following.

As shown in FIG. 2A (PRIOR ART), when the location of the opening 133 in the solder mask layer 13 is accurate and with no deviation, both the first bonding point and the second bonding point of the bonding wire 173 can be precisely bonded onto, for example, the bond pad 171 of the chip 17 and the electrical connection portion 15 respectively, wherein the second bonding point is aligned with the central point of the electrical connection portion 15 so that wire arc of the bonding wire 173 can be avoided from touching any edge of the corresponding opening 133 in the solder mask layer 13.

On the other hand, as shown in FIG. 2B (PRIOR ART), when the location of the opening 133 in the solder mask layer 13 deviates toward the right side in the drawing (but still within the range of ±75 μm), the second bonding point of the bonding wire 173 is still bonded onto the central point of the electrical connection portion 15 without any automatic compensation, so that the wire arc of the bonding wire 173 may touch an edge on the left side of the corresponding opening 133 in the solder mask layer 13. Accordingly, various bonding failures, such as bending, low coupling force, cracking, and detachment of the bonding wire 173 may be caused by the undesirable contact between the bonding wire and the edge of the opening in the solder mask layer. If the position deviation of the opening 133 is larger, the second bonding point may even be directly bonded onto a surface of the solder mask layer 13. Any of the bonding failures of the bonding wire 173, including bending, low coupling force, cracking, and detachment caused by the position deviation of the opening 133, would result in a yield reduction of the wire-bonding process, thereby incurring costs for defective products and increasing the overall fabrication cost.

Disclosures in U.S. Pat. No. 6,468,813 and U.S. Pat. No. 6,668,449 are both related to an approach in which the forgoing fiducial mark is provided on the substrate to be used for determining coordinate data in the die bonding process along with details of the chip that is positioned in the die bonding process in order to perform the wire-bonding process so as to prevent the positions of the first bonding point and the second bonding point from being deviated. However, this approach does not address the bonding failure which is caused by the position deviation of the solder mask layer.

U.S. Pat. No. 6,468,813 discloses a method for automatically detecting product quality and skipping a defective product during the wire-bonding process. In the method, a reject eye provided above a chip mounting area is used to automatically determine whether a skipping procedure should be executed or not. However, in such a method, a product is only judged as a defective one if a position deviation of a solder mask layer has been observed, without any attempt to adjust for such deviation to improve the product yield. Moreover, this method is only suitable for skipping a defective product in which the position deviation of the opening of the solder mask layer has such a large deviation that the reject eye only sees the opening of the solder mask layer. For the case that an opening of the solder mask layer in a product has a position deviation that doesn't completely occupy the view of the reject eye, the forgoing bonding failure of the second bonding point may be caused since the product is not judged as a defective one and the wire-bonding process is still performed without any compensation. Thus, the yield of the wire-bonding process may be decreased, resulting in expenditure on the defective products and increasing the overall fabrication cost.

Hence, there has an urgent need in the art to develop semiconductor packaging technology for solving the forgoing drawbacks, in which the second bonding point can be re-positioned to compensate for any position deviation of the opening of the solder mask layer during the wire-bonding process, to thereby avoid the problems of defective bonding wires such as bending, cracking, or detachment of the bonding wires caused by the undesirable contact between the bonding wires and the solder mask layer in the conventional wire bonding process, thus increasing the product yield in the wire-bonding process, thereby saving cost on the defective products and decreasing the overall fabrication cost.

### SUMMARY OF THE INVENTION

In view of the forgoing and other drawbacks, an objective of the present invention is to provide a bond positioning method for a wire-bonding process and a substrate for the bond positioning method to re-define the positioning of a bonding point of a bonding wire according to a deviation of a solder mask layer.

Another objective of the present invention is to provide a bond positioning method for a wire-bonding process and a substrate for the bond positioning method for preventing a bonding wire from contact with any edges of the solder mask layer.

Still another objective of the present invention is to provide a bond positioning method for a wire-bonding process and a substrate for the bond positioning method for avoiding bonding failure caused by position deviation of the solder mask layer.

Still another objective of the present invention is to provide a bond positioning method for a wire-bonding process and a substrate for the bond positioning method for improving the product yield of the wire-bonding process, so as to save cost on defective products and reduce the overall fabrication cost.

For attaining the above and other objectives, the present invention provides a bond positioning method for a wire-bonding process that redefines the positioning of a second bonding point of a bonding wire bonded to a substrate which has been provided with a solder mask layer and a chip on a surface thereof, the method comprising the steps of: forming at least one solder mask mark in the solder mask layer on the substrate in advance; determining deviation of the solder mask layer with the solder mask layer mark serving as a reference point; and performing coordinate compensation according to the deviation so as to re-define positioning of the second bonding point of the bonding wire.

Preferably, a predetermined xy-coordinate pair of the solder mask mark serves as a data point, and an xy-coordinate pair of the solder mask mark serves as a reference point, while the distance between the data point and the reference point or a vector from the data point to the reference point is taken as the deviation of the solder mask layer, wherein the data point is the predetermined xy-coordinate pair of the central point of the solder mask mark, and the reference point is the xy-coordinate pair of the central point of the solder mask mark.

The present invention also provides a substrate for the above-described method, the substrate at least comprising: a plurality of conductive traces and a plurality of electrical connection portions formed on a surface of the substrate; a solder mask layer for covering the plurality of conductive traces and exposing the plurality of electrical connection portions; a chip mounting area for mounting a chip thereon; and a solder mask mark formed in the solder mask layer for serving as a reference point for determining deviation of the solder mask layer and performing coordinate compensation according to the deviation so as to re-define positioning of a second bonding point of a bonding wire.

The solder mask mark is an opening formed in the solder mask layer wherein a metal pad formed on the substrate is exposed through the opening. The metal pad is preferably formed of a part of the conductive traces on the surface of the substrate. The metal pad is formed with a pattern with which a central point of the metal pad can be calculated, wherein the pattern is preferably selected from a group consisting of a cross, square, rectangle, circle, ellipse, diamond, equiangular triangle, and equiangular polygon. Moreover, an electroplating layer may be optionally provided on a surface of the metal pad, wherein the electroplating layer is preferably comprised of a metal of one of gold, palladium and silver, or a metallic material selected from the group consisting of nickel-gold, nickel-palladium and nickel-silver alloy. Furthermore, the size of the opening may be smaller than that of the metal pad, while the shape of the opening is a pattern with which a central point of the opening can be calculated, wherein the pattern is preferably selected from the group consisting of a cross, square, rectangle, circle, ellipse, diamond, equiangular triangle, and equiangular polygon.

A substrate mark for positioning the substrate is also provided on the substrate. Preferably, the substrate mark is a metal pad formed on the substrate, and a corresponding opening in formed in the solder mask layer to expose the metal pad. Preferably, the size of the metal pad is smaller than that of the opening. Moreover, the metal pad is preferably formed of a part of the conductive traces. Furthermore, an electroplating layer may be provided on a surface of the metal pad, wherein the electroplating layer is preferably comprised of a metal of one of gold, palladium and silver, or a metallic material selected from the group consisted of nickel-gold, nickel-palladium and nickel-silver alloy.

Alternatively, a substrate mark superimposed with the solder mask mark for positioning the substrate may be provided on the substrate. Preferably, the substrate mark is formed of a hollow part of a metal pad, while the solder mask mark is an opening formed in the solder mask layer to allow the metal pad to be exposed through the opening, wherein the size of the opening is smaller than that of the metal pad, and the size of the hollow part is smaller than that of the opening. The hollow part and/or the opening may be formed with a pattern with which a central point of the hollow part and/or the opening can be calculated, wherein the pattern is preferably selected from the group consisting of a cross, square, rectangle, circle, ellipse, diamond, equiangular triangle, and equiangular polygon. The metal pad may be formed of a part of the conductive traces on the surface of the substrate. Moreover, an electroplating layer may be provided on a surface of the metal pad, wherein the electroplating layer is preferably comprised of a metal of one of gold, palladium and silver, or a metallic material selected from the group consisting of nickel-gold, nickel-palladium and nickel-silver alloy.

In addition, the substrate is a Ball Grid Array substrate. The second bonding point of each of the bonding wires is arranged at a corresponding electrical connection portion of the substrate, while the electrical connection portion is one of the ground ring, power ring, and finger.

In the bond positioning method for the wire-bonding process, at least one solder mask mark is formed in advance in the solder mask layer on the substrate, such that, during the wire-bonding process, this solder mask mark serves as a reference point for determining deviation of the solder mask layer and performing coordinate compensation according to the deviation so as to re-define positioning of the second bonding point of the bonding wire. This can overcome the problems of defective bonding wires such as bending, cracking, or detachment of the bonding wires caused by undesirable contact between the bonding wires and the solder mask layer in the conventional wire-bonding process since the positioning of the second bonding point is re-defined according to the deviation of the solder mask layer, thereby improving the product yield of the wire-bonding process, saving cost on defective products, and reducing the overall fabrication cost.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a view showing a structure of a conventional ball grid array substrate;

FIG. 2A (PRIOR ART) is a view showing a wire-bonding process in which the position of a solder mask layer of a conventional ball grid array substrate is without deviation;

FIG. 2B (PRIOR ART) is a view showing a wire-bonding process in which the position of a solder mask layer of a conventional ball grid array substrate is deviated;

FIG. 3A is a view showing a substrate structure according to the first embodiment of the present invention;

FIG. 3B is a view showing a substrate structure according to the second embodiment of the present invention;

FIG. 3C is a view showing a substrate structure according to the third embodiment of the present invention;

FIG. 4A is a view showing a wire-bonding process in which the position of a solder mask layer according to the present invention is without deviation;

FIG. 4B is a view showing a wire-bonding process in which the position of a solder mask layer according to the present invention is deviated;

FIG. 5A is a view showing a substrate structure according to the fourth embodiment of the present invention;

FIG. 5B is a view showing a substrate structure according to the fifth embodiment of the present invention;

FIG. 5C is a view showing a substrate structure according to the sixth embodiment of the present invention; and

FIG. 6 a view showing a wire-bonding process in which the position of the solder mask layer shown in FIG. 5A is deviated.

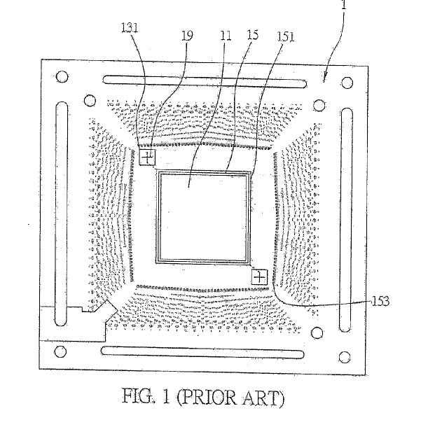

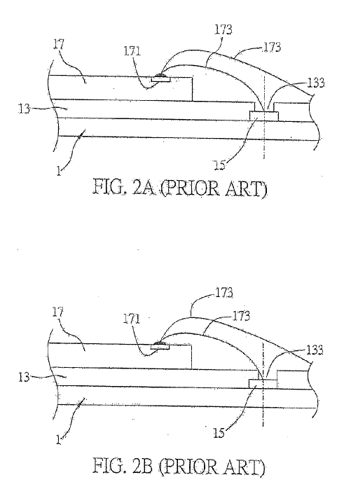

### DETAILED DESCRIPTION OF THE PREFERRED EMBODIMENTS

The present invention will be described in detail with specific embodiments. However, the embodiments are illustrative in nature and are not intended to limit the scope or the spirit of the present invention. In particular, though a ball grid array substrate is illustrated in the description and the accompanying drawings to facilitate understanding of the present invention, the bond positioning method for a wire-bonding process and the substrate for the method provided in the present invention can be applied in various semiconductor packages with a substrate used as chip carrier.

### First Embodiment

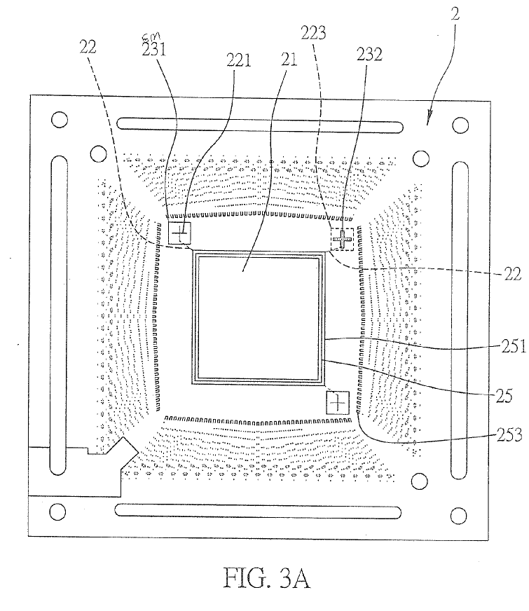

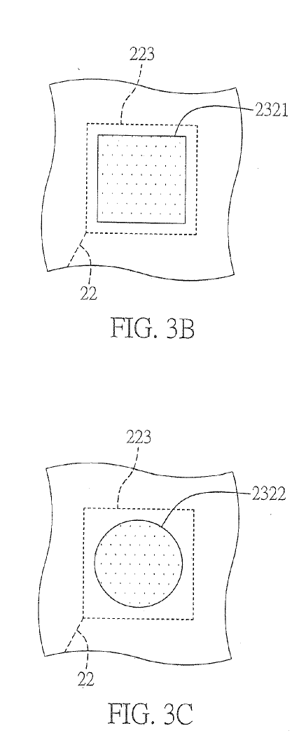

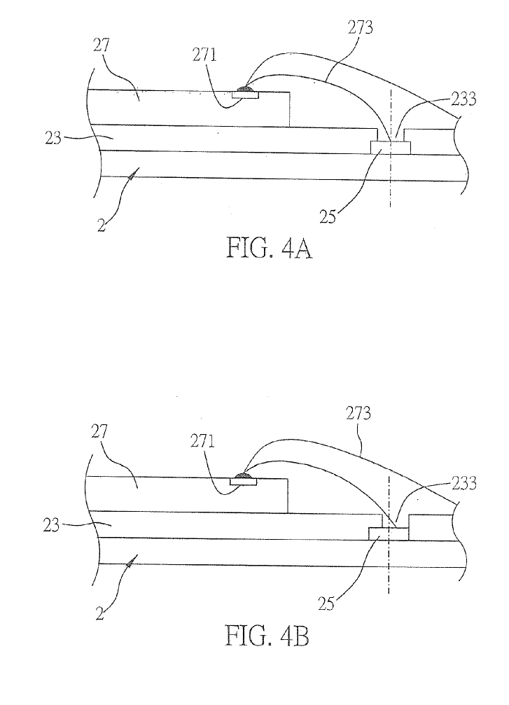

Referring to FIGS. 3A and 4A, a chip mounting area 21 such as a die pad is defined at a central portion on an upper surface of a ball grid array substrate 2, for example, and a plurality of electrical connection portions 25, 251 and 253 are provided around the chip mounting area 21, wherein the electrical connection portions are formed of parts of conductive traces and exposed from a surface of a solder mask layer 23. By a die bonding apparatus, the chip mounting area 21 is dispensed with a paste material, and a chip 27 is then attached thereon and thermally cured, thus completing a die bonding process. A plurality of bonding wires 273 are bonded between corresponding bond pads 271 (FIG. 4A) and the electrical connection portions 25, 251 and 253 by a wire bonding apparatus, thereby completing a wire-bonding process.

In order to allow the die bonding apparatus to perform the die bonding process with high positioning accuracy, at least one substrate mark 221 is formed in advance on the upper surface of the substrate 2. The substrate mark 221 is a metal pad with, for example, a cross shape, and is also formed of a part of the conductive traces 22 with an electroplating layer such as a Ni/Au layer plated thereon. An opening 231 corresponding to the substrate mark 221 is formed in the solder mask layer 23 so as to allow the substrate mark 221 to be exposed through the opening 231 and recognized by an image capturing unit of the die bonding apparatus for determining coordinate data. The size of the substrate mark 221, which is for example a cross-shaped metal pad, is smaller than that of the opening 231, such that the central point of the substrate mark 221 can still be recognized even when the solder mask layer 23 is deviated (within ±75 μm).

Moreover, at least one solder mask mark 232 is also provided in advance in the solder mask layer 23. In the present embodiment, the solder mask mark 232 is, for example, a cross-shaped opening formed in the solder mask layer 23. A metal pad 223 formed on the substrate 2 is exposed through the opening, wherein the metal pad is also a part of the conductive traces 22 with an electroplating layer such as a Ni/Au layer plated thereon. The size of the solder mask mark 232, which is cross-shaped for example, is smaller than that of the metal pad 223, such that the central point of the solder mask mark 232 can still be recognized by a significant color difference between the solder mask layer 23 and the metal pad 223 even when the solder mask layer 23 is deviated (within ±75 μm). Generally, the color of the solder mask layer 23 is dark green, and the color of the metal pad 223 is golden.

Since the substrate mark 221 is formed of a part of the conductive traces 22 of the substrate 2, the relative positions between the substrate mark 221 and the die pad 21 as well as the electrical connection portions 25, 251 and 253 are definitely not changed. Therefore, once the substrate mark 221 is recognized by the image capturing unit of the die bonding apparatus and the coordinate data is determined, an xy-coordinate pair for the die bonding process is determined, and an xy-coordinate pair for the subsequent wire-bonding process is also determined with respect to data for the chip 27, whereby a first bonding point and a second bonding point for each of the bonding wires 273 can be accurately bonded onto the bond pad 271 of the chip 27 and the electrical connection portion 25 respectively.

However, when there is a position deviation (within ±75 μm) of the solder mask layer 23 occurring with respect to the substrate 2, positions of each of the openings, which correspond to the electrical connection portions and the marks respectively, are deviated correspondingly. For the electrical connection portions 25, 251 and 253, the position deviation of the corresponding openings thereof would result in various bonding failures such as detachment, bending, or cracking of the bonding wires. The electrical connection portions 25, 251 and 253 are generally classified into ground ring, power ring and finger according to functionality. Since there is no difference between the wire-bonding processes for those different portions, only the wire-bonding process for the electrical connection portion 25, which represents the ground ring will be described as follows.

As shown in FIG. 4A, when the location of the opening 233 in the solder mask layer 23 is accurate and with no position deviation, both the first bonding point and the second bonding point of the bonding wire 273 can be precisely bonded onto, for example, the bond pad 271 of the chip 27 and the electrical connection portion 25 of the substrate, respectively, wherein the second bonding point is generally aligned with the central point of the electrical connection portion 25 so that the wire arc of the bonding wire 273 can avoid contact with any of the edges of the corresponding opening 233 in the solder mask layer 23.

On the other hand, as shown in FIG. 4B, when the location of the opening 233 in the solder mask layer 23 deviates toward the right side in the drawing (but still within the range of ±75 μm), bonding failures would be caused if the second bonding point of the bonding wire 273 is still bonded onto the central point of the electrical connection portion 15, that is, bonded without any compensation. Therefore, it is useful to initially determine an actual xy-coordinate pair of the solder mask mark 232 by the image capturing unit provided in the die bonding apparatus or the wire bonding apparatus. Thereby, a predetermined xy-coordinate pair of the solder mask mark 232 is utilized as a data point, and the actual xy-coordinate pair of the solder mask mark 232 is utilized as a reference point, wherein a result obtained by calculating a distance between the data point and the reference point is taken as the deviation of the solder mask layer 23. Then, the coordinate is compensated toward the right side according to the resulting deviation, so as to re-define the positioning of the second bonding point. According to the wire-bonding process performed with the re-defined coordinate, the second bonding point of the bonding wire 273 is slightly deviated toward the right side. Specifically, the second bonding point is deviated from the central point of the electrical connection portion 25 toward the right side to an extent in accordance with the deviation. Thus, the second bonding point of the bonding wire 273 is still bonded at the central position of the opening 233 in the deviated solder mask layer 23, but overcomes the problems of defective bonding wires such as bending, cracking, or detachment of the bonding wires caused by the deviation of the solder mask layer 23 by positioning the bonding wire 273 away from the edges of the opening 233 in the solder mask layer 23.

While the actual xy-coordinate pair of the solder mask mark 232 is recognized as described-above, the xy-coordinate pair of the central point of the solder mask mark 232, such as a cross-shaped opening, is used as the actual xy-coordinate pair. The same applies for the substrate mark 221.

Furthermore, though the present embodiment is exemplified by a case in which the distance between the data point and the reference point is calculated and utilized as the deviation of the solder mask layer 23, the present invention is not limited to the use of such a one-dimensional deviation. A vector from the data point to the reference point may be calculated and utilized as the deviation of the solder mask layer 23, and thus a two-dimensional vector compensation of the coordinate can be performed according to this vector deviation.

### Second Embodiment

Referring to FIG. 3B, a substrate structure according to the second embodiment of the present invention is illustrated. Since the major difference between the present embodiment and the first embodiment is the solder mask mark 2321, only a partial enlarged view of the substrate is shown, so as to clarify the present embodiment. Also, elements that are the same with those depicted in the first embodiment are designated with the like numerals. Detailed description for elements not shown in the drawing is omitted. As shown in the drawing, the solder mask mark 2321 is a square opening formed in the solder mask layer, while a metal pad 223 formed on the substrate is exposed through the opening. Similarly, the metal pad 223 is a part of the conductive traces 22, and is electroplated with an electroplating layer such as a Ni/Au layer on a surface thereof. When determining the actual xy-coordinate pair of the solder mask mark 2321, the xy-coordinate pair of the central point of the solder mask mark 2321 can be obtained by calculating the intersection of two diagonal lines of the square opening thereof. Thus, in the wire-bonding process, the deviation of the solder mask layer can be calculated with the xy-coordinate pair of the central point serving as the reference point. Herein, the calculation of the deviation and the re-definition of the positioning of the second bonding point of the bonding wire will not be described again since they have been explicitly described in the first embodiment.

### Third Embodiment

Referring to FIG. 3C, a substrate structure according to the third embodiment of the present invention is illustrated. Since the major difference between the present embodiment and the first embodiment is the solder mask mark 2322, only a partial view (enlarged) of the substrate is shown, so as to clarify the present embodiment. Also, elements that are the same with those depicted in the first embodiment are designated with the like numerals. Detailed description for elements not shown in the drawing is omitted. As shown in the drawing, the solder mask mark 2322 is a circular opening formed in the solder mask layer, while a metal pad 223 formed on the substrate is exposed through the opening. Similarly, the metal pad 223 is a part of the conductive traces 22, and is electroplated with an electroplating layer such as a Ni/Au layer on a surface thereof. When determining the actual xy-coordinate pair of the solder mask mark 2322, the xy-coordinate pair of the central point of the solder mask mark 2322 can be obtained by calculating the intersection of any two diameters of the circular opening thereof. Thus, in the wire-bonding process, the deviation of the solder mask layer can be calculated with the xy-coordinate pair of the central point serving as the reference point. Herein, the calculation of the deviation and the re-definition of the positioning of the second bonding point of the bonding wire will not be described again since they have been explicitly described in the first embodiment.

The solder mask marks in the forgoing embodiments are all formed with patterns in which a central point can be calculated. Therefore, it should be noted that the pattern of the solder mask mark and the substrate mark is not limited to the above-depicted cross shape, square shape or circular shape, and other pattern such as a rectangle, ellipse, diamond, equiangular triangle, and equiangular polygon may also be adopted as long as the central point of the pattern is available.

### Fourth Embodiment

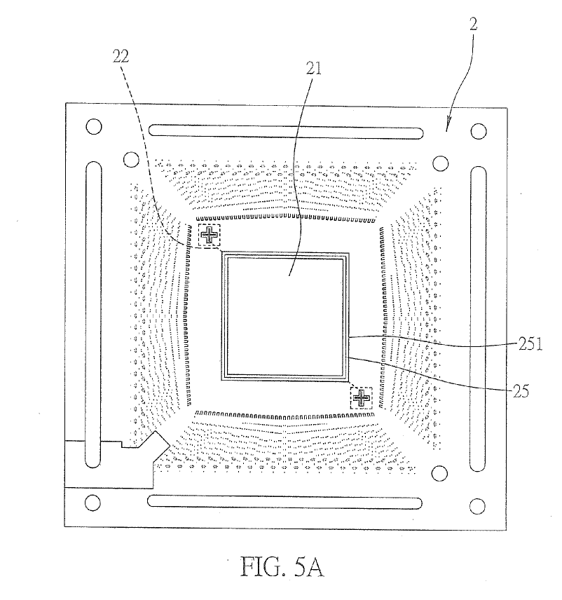

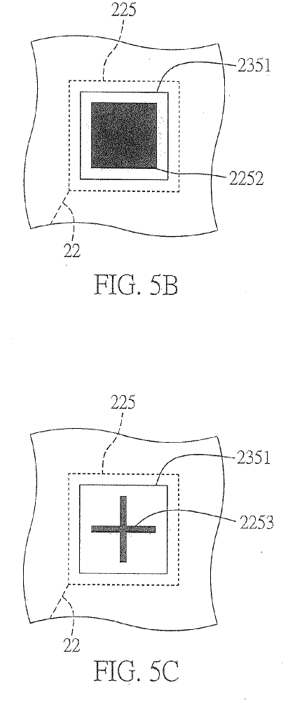

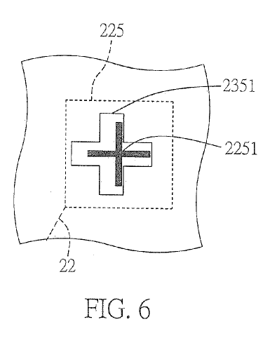

Referring to FIG. 5A, a substrate structure according to the fourth embodiment of the present invention is illustrated. The major difference between the present embodiment and the first embodiment is that the solder mask mark is superimposed with the substrate mark. To clarify the present embodiment, elements that are the same with those depicted in the first embodiment are designated with the like numerals. Detailed description for other elements not shown in the drawing is omitted.

As shown in FIG. 5A and FIG. 6, a substrate 2 is at least provided with a substrate mark 2251 and a solder mask mark 2351 superimposed with each other. The substrate mark 2251 is formed of a cross-shaped hollow part of a metal pad 225, and the solder mask mark 2351 is a cross-shaped opening formed in the solder mask layer to allow the metal pad 225 to be exposed at the opening. Similarly, the metal pad 225 may be a part of the conductive traces 22, and may be electroplated with an electroplating layer such as a Ni/Au layer on a surface thereof.

The size of the solder mask mark 2351 (i.e. the cross-shaped opening) is smaller than that of the metal pad 225, and the size of substrate mark 2251 (i.e. the cross-shaped hollow part) is smaller than that of the solder mask mark 2351. In determining the actual coordinates of the solder mask mark 2351, the coordinates of the central point of the solder mask mark 2351 can be obtained by calculating the intersection of the cross-shaped opening thereof. In determining the actual coordinates of the substrate mark 2251, the coordinates of the central point of the substrate mark 2251 can be obtained by calculating the intersection of the cross-shaped hollow part thereof.

As an example, FIG. 6 shows a case wherein the solder mask layer is deviated toward the left side in the drawing (within the range of ±75 μm). However, the actual coordinates of the solder mask mark 2351 are recognized by the image-capture unit provided in the die bonding apparatus or the wire bonding apparatus. Thus, the predetermined coordinates of the solder mask mark 2351 are utilized as a data point, and the actual coordinates of the solder mask mark 2351 are utilized as a reference point, and a result obtained by calculating a distance or a vector between the data point and the reference point is taken as the deviation of the solder mask layer. Then, the coordinates are compensated toward the left side according to the resulting deviation, so as to re-define the positioning of the second bonding point.

In the present embodiment, an integrated mark configuration in which the solder mask mark 2351 is superimposed with the substrate mark 2251 is illustrated, wherein such configuration facilitates the image capturing unit provided in the die bonding apparatus or the wire bonding apparatus to recognize the marks quickly from one position, without the necessity to be moved between multiple positions, thereby increasing the recognition speed. Herein, the calculation of the deviation and the re-definition of the positioning of the second bonding point of the bonding wire will not be described again since they have been explicitly described in the first embodiment.

### Fifth Embodiment

Referring to FIG. 5B, a substrate structure according to the fifth embodiment of the present invention is illustrated. Since the major difference between the present embodiment and the fourth embodiment is the superimposition configuration of the solder mask mark 2351 and the substrate mark 2252, only a partial enlarged view of the substrate is shown so as to clarify the present embodiment. Also, elements that are the same with those depicted in the fourth embodiment are designated with the same numerals. Detailed description for other elements not shown in the drawing is omitted. As shown in the drawing, the substrate mark 2252 is a square hollow part formed in a metal pad 225, and the solder mask mark 2351 is a square opening formed in the solder mask layer, the metal pad 225 formed on the substrate being exposed at the opening. Similarly, the metal pad 225 may be a part of the conductive traces 22, and may be electroplated with an electroplating layer such as a Ni/Au layer on a surface thereof. In determining the actual coordinates of the solder mask mark 2351, the coordinates of the central point of the solder mask mark 2351 can be obtained by calculating the intersection of two diagonal lines of the square opening thereof. Also, the actual coordinates of the substrate mark 2252 can be obtained in the same way. Thus, in the wire-bonding process, the deviation of the solder mask layer can be calculated with the coordinates of the central point serving as the reference point. Herein, the calculation of the deviation and the re-definition of the positioning of the second bonding point of the bonding wire will not be described again since they have been explicitly described in the first embodiment.

### Sixth Embodiment

Referring to FIG. 5C, a substrate structure according to the sixth embodiment of the present invention is illustrated. Since the major difference between the present embodiment and the fourth embodiment is the superimposition configuration of the solder mask mark 2351 and the substrate mark 2253, only a partial, enlarged view of the substrate is shown so as to clarify the present embodiment. Also, elements that are the same with those depicted in the fourth embodiment are designated with the same numerals. Detailed description for other elements not shown in the drawing is omitted. As shown in the drawing, the substrate mark 2253 is a cross-shaped hollow part formed in a metal pad 225, and the solder mask mark 2351 is a square opening formed in the solder mask layer, the metal pad 225 formed on the substrate being exposed at the opening. Similarly, the metal pad 225 may be a part of the conductive traces 22, and may be electroplated with an electroplating layer such as a Ni/Au layer on a surface thereof. When determining the actual coordinates of the substrate mark 2353, the coordinates of the central point of the substrate mark 2353 can be obtained by calculating the intersection of the cross-shaped hollow part thereof. Herein, the calculation of the deviation and the re-definition of the positioning of the second bonding point of the bonding wire will not be described again since they have been explicitly described in the first embodiment.

As described above, in the bond positioning method for the wire-bonding process, at least one solder mask mark is formed in advance in the solder mask layer on the substrate, such that, during the wire-bonding process, this solder mask mark serves as a reference point for determining deviation of the solder mask layer and performing coordinate compensation according to the deviation so as to re-define positioning of the second bonding point of the bonding wire. This can overcome the problems of defective bonding wires such as bending, cracking, or detachment of the bonding wires caused by the undesirable contact between the bonding wires and the solder mask layer in the conventional wire-bonding process since the positioning of the second bonding point is re-defined according to the deviation of the solder mask layer, thereby improving the product yield of the wire-bonding process, saving cost on defective products and reducing the overall fabrication cost. Therefore, the bond positioning method for the wire-bonding process and the substrate for the bond positioning method proposed in the present invention can overcome various drawbacks of the conventional technology, bring significant improvement with high industry applicability.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A bond positioning method for a wire-bonding process for re-defining positioning of a second bonding point of a bonding wire bonded to a substrate which has been provided with a solder mask layer and a chip on a surface thereof, the bond positioning method comprising the steps of:
forming at least one solder mask mark in the solder mask layer on the substrate;
determining deviation of the solder mask layer with the solder mask mark serving as a reference point; and
performing coordinate compensation according to the deviation so as to re-define positioning of the second bonding point of the bonding wire.

2. The bond positioning method of claim 1, wherein a predetermined xy-coordinate pair of the solder mask mark serves as a data point, and an actual xy-coordinate pair of the solder mask mark serves as a reference point, wherein a distance between the data point and the reference point is taken as the deviation of the solder mask layer.

3. The bond positioning method of claim 1, wherein a predetermined xy-coordinate pair of the solder mask mark serves as a data point, and an actual xy-coordinate pair of the solder mask mark serves as a reference point, wherein a vector from the data point to the reference point is taken as the deviation of the solder mask layer.

4. The bond positioning method of claim 2, wherein the data point is a predetermined xy-coordinate pair of a central point of the solder mask mark, and the reference point is an actual xy-coordinate pair of a central point of the solder mask mark.

5. The bond positioning method of claim 3, wherein the data point is a predetermined xy-coordinate pair of a central point of the solder mask mark, and the reference point is an actual xy-coordinate pair of a central point of the solder mask mark.

6. The bond positioning method of claim 1, wherein the solder mask mark is an opening formed in the solder mask layer, and a metal pad provided on the substrate is exposed through the opening.

7. The bond positioning method of claim 6, wherein the opening of the solder mask mark is smaller in size than the metal pad on the substrate.

8. The bond positioning method of claim 6, wherein the opening of the solder mask mark is a pattern in which a central point is available.

9. The bond positioning method of claim 8, wherein the pattern of the opening of the solder mask mark is selected from the group consisting of a cross, square, rectangle, circle, ellipse, diamond, equiangular triangle, and equiangular polygon.

10. The bond positioning method of claim 1, wherein the substrate further comprises a substrate mark for positioning a substrate xy-coordinate pair.

11. The bond positioning method of claim 10, wherein the substrate mark is a metal pad provided on the substrate, and a corresponding opening is formed in the solder mask layer to expose the metal pad.

12. The bond positioning method of claim 11, wherein the metal pad of the substrate mark is smaller in size than the opening of the solder mark layer.

13. The bond positioning method of claim 1, wherein the substrate further comprises a substrate mark for positioning a substrate xy-coordinate pair, the substrate mark being superimposed with the solder mask mark.

14. The bond positioning method of claim 13, wherein the substrate mark is a hollow part formed in a metal pad, and the solder mask mark is an opening formed in the solder mask layer, with the metal pad being exposed through the opening.

15. The bond positioning method of claim 14, wherein the opening of the solder mask mark is smaller in size than the metal pad with the substrate mark, and the hollow part of the substrate mark is smaller in size than the opening of the solder mask mark.

16. The bond positioning method of claim 14, wherein the hollow part of the substrate mark is a pattern in which a central point is available.

17. The bond positioning method of claim 14, wherein the opening of the solder mask mark is a pattern in which a central point is available.

18. The bond positioning method of claim 16, wherein the pattern of the hollow part of the substrate mark is selected from the group consisting of a cross, square, rectangle, circle, ellipse, diamond, equiangular triangle, and equiangular polygon.

19. The bond positioning method of claim 17, wherein the pattern of the opening of the solder mask mark is selected from the group consisting of a cross, square, rectangle, circle, ellipse, diamond, equiangular triangle, and equiangular polygon.

20. A substrate for packaging a chip, comprising:
a plurality of conductive traces and a plurality of electrical connection portions formed on a surface of the substrate;
a solder mask layer for covering the plurality of conductive traces and exposing the plurality of electrical connection portions;
a chip mounting area for mounting the chip thereon; and
a solder mask mark formed in the solder mask layer, for serving as a reference point for determining deviation of the solder mask layer and performing coordinate compensation according to the deviation so as to re-define positioning of a second bonding point of a bonding wire.

21. The substrate of claim 20, wherein the solder mask mark is an opening formed in the solder mask layer, and a metal pad provided on the substrate is exposed through the opening.

22. The substrate of claim 20, wherein the opening of the solder mask mark is smaller in size than the metal pad on the substrate.

23. The substrate of claim 20, wherein the opening of the solder mask mark is a pattern in which a central point is available.

24. The substrate of claim 23, wherein the pattern of the opening of the solder mask mark is selected from the group consisting of a cross, square, rectangle, circle, ellipse, diamond, equiangular triangle, and equiangular polygon.

25. The substrate of claim 20, further comprising a substrate mark for positioning a substrate xy-coordinate pair.

26. The substrate of claim 25, wherein the substrate mark is a metal pad provided on the substrate, and a corresponding opening is formed in the solder mask layer to expose the metal pad.

27. The substrate of claim 20, wherein the metal pad of the substrate mark is smaller in size than the opening of the solder mask layer.

28. The substrate of claim 27, wherein the metal pad of the substrate mark is a pattern in which a central point is available.

29. The substrate of claim 28, wherein the pattern of the metal pad of the substrate mark is selected from the group consisting of a cross, square, rectangle, circle, ellipse, diamond, equiangular triangle, and equiangular polygon.

30. The substrate of claim 20, further comprising a substrate mark for positioning a substrate xy-coordinate pair, wherein the substrate mark is superimposed with the solder mask mark.

31. The substrate of claim 30, wherein the substrate mark is a hollow part formed in a metal pad, and the solder mask mark is an opening formed in the solder mask layer, with the metal pad being exposed through the opening.

32. The substrate of claim 31, wherein the opening of the solder mask mark is smaller in size than the metal pad with the substrate mark, and the hollow part of the substrate mark is smaller in size than the opening of the solder mask mark.

33. The substrate of claim 31, wherein the hollow part of the substrate mark is a pattern in which a central point is available.

34. The substrate of claim 31, wherein the opening of the solder mask mark is a pattern in which a central point is available.

35. The substrate of claim 33, wherein the pattern of the hollow part of the substrate mark is selected from the group consisting of a cross, square, rectangle, circle, ellipse, diamond, equiangular triangle, and equiangular polygon.

36. The substrate of claim 34, wherein the pattern of the opening of the solder mask mark is selected from the group consisting of a cross, square, rectangle, circle, ellipse, diamond, equiangular triangle, and equiangular polygon.
